(19) United States
(12) Patent Application Publication
(10) Pub. No.: US 2026/0344165 A1
(43) Pub. Date: Oct. 29, 2026

(54) MICRO/NANO LED APPARATUS AND MANUFACTURING METHOD THEREFOR

(71) Applicant: Beijing Zitiao Network Technology Co., Ltd., Beijing (CN)

(72) Inventors: Duo LI, Beijing (CN); Chenggong WANG, Beijing (CN); Zhen HUANG, Beijing (CN); Xiaokai LI, Beijing (CN)

(21) Appl. No.: 19/114,320

(22) PCT Filed: Apr. 25, 2024
(86) PCT No.: PCT/CN2024/089763

§ 371 Date: Mar. 21, 2025

(30) Foreign Application Priority Data
May 5, 2023 (CN) 202310499213.2

(51) Int. Cl. H10H 29/856; H10H 20/825; H10H 29/01

(52) U.S. Cl. CPC H10H 29/856; H10H 29/0363; H10H 20/825

(57) ABSTRACT

The present disclosure provides a Micro/Nano LED apparatus and a manufacturing method thereof. The Micro/Nano LED apparatus comprises a driving backboard, a plurality of LED units arranged in an array, and a plurality of first DBR structures, the LED units being located on one side of the driving backboard, the first DBR structures being located between adjacent LED units, and adjacent first DBR structures forming vertical resonant cavity.

### CROSS-REFERENCE TO RELATED APPLICATION(S)

The present application is based on and claims priority of Chinese Patent Application No. 202310499213.2, filed on May 5, 2023, the disclosure of which is incorporated herein by reference in its entirety.

### TECHNICAL FIELD

The present disclosure belongs to the field of display technology, and in particular, relates to a Micro/Nano LED apparatus and a manufacturing method thereof.

### BACKGROUND

As a new display technology, Micro/Nano LED is very suitable for the field of augmented reality (AR) due to its advantages of high contrast, high brightness, high reliability, low power consumption, long service life, and fast response. Existing mainstream AR terminal devices adopt technical solutions such as Micro/Nano LED, LCOS, LBS, or the like. In the technical solution, a Micro/Nano LED light engine is used in cooperation with a diffractive optical waveguide for image transmission and full-color light combination, and a pixel light field of the light engine needs to be coupled into the waveguide through a diffractive grating for transmission.

However, the diffractive grating that is usually used has a strong dispersion effect. Even if the coupling grating is designed in a matching manner for Micro/Nano LED light engines of each of red (R), green (G), and blue (B) colors, when the line width of the emission spectrum of the light engine is relatively large, the dispersion effect will inevitably occur. The larger the line width of the emission spectrum, the more obvious the dispersion effect is. The strong dispersion effect will lead to a serious reduction in system light efficiency. At present, the line width of the emission spectrum of InGaN-based blue and green Micro/Nano LEDs is 10-20 nm, while the line width of the emission spectrum of red Micro/Nano LEDs is broadened to above 50 nm due to In component segregation, which brings very serious coupling-in loss. In addition, a lens group is used between the Micro/Nano LED display screen and the incident grating to realize collimation of light. If the far-field light divergence angle of the Micro/Nano LED is reduced, it will be beneficial to reduce the distance between the entrance pupil and the exit pupil of the lens, thereby providing more degrees of freedom for the optical path design of the AR terminal device.

Therefore, effectively controlling the emission half width and the far-field divergence angle of the Micro/Nano LED has very important guiding significance for the optical path design of AR/VR devices.

### SUMMARY

The present disclosure aims at least to improve at least one of the above technical problems to a certain extent.

The present disclosure provides a Micro/Nano LED apparatus, including: a driving backboard, a plurality of LED units arranged in an array, and a plurality of first DBR structures, where the LED units are located on one side of the driving backboard, the first DBR structures are located between adjacent LED units, and the adjacent first DBR structures form a vertical resonant cavity.

According to an embodiment of the present disclosure, the first DBR structure includes multiple pairs of first high-refractive-index layers and first low-refractive-index layers that are arranged alternately; and the first high-refractive-index layers and the first low-refractive-index layers are perpendicular to the driving backboard.

According to an embodiment of the present disclosure, the Micro/Nano LED apparatus further includes a plurality of bonding units arranged at intervals, and the bonding units are located between the driving backboard and the LED units.

According to an embodiment of the present disclosure, the Micro/Nano LED apparatus further includes second DBR structures, the second DBR structures are located between adjacent bonding units, and the second DBR structures are located on a side of the first DBR structures close to the driving backboard; a side of the LED units away from the driving backboard is provided with a metal electrode layer; and the metal electrode layer and the second DBR structures form a horizontal resonant cavity.

According to an embodiment of the present disclosure, a material for forming the metal electrode layer includes at least one of silver, aluminum, and gold; the second DBR structure includes multiple pairs of second high-refractive-index layers and second low-refractive-index layers that are arranged alternately; and the second high-refractive-index layers and the second low-refractive-index layers are parallel to the driving backboard.

According to an embodiment of the present disclosure, the Micro/Nano LED apparatus satisfies at least one of the following conditions: a material for forming the first high-refractive-index layers and a material for forming the second high-refractive-index layers include TiO₂; a material for forming the first low-refractive-index layers and a material for forming the second low-refractive-index layers include SiO₂; the first DBR structure includes multiple periods, each period of the first DBR structure includes a first high-refractive-index layer and a first low-refractive-index layer that are arranged in a stacked manner, and the first DBR structure includes 10 periods; the second DBR structure includes multiple periods, each period of the second DBR structure includes a second high-refractive-index layer and a second low-refractive-index layer that are arranged in a stacked manner, and the second DBR structure includes 15 or more periods; a thickness of the second high-refractive-index layer is the same as that of the first high-refractive-index layer, and a thickness of the second low-refractive-index layer is the same as that of the first low-refractive-index layer; and the LED unit includes a p-type GaN layer, an MQW layer, and an n-type GaN layer that are arranged in a stacked manner, and the p-type GaN layer is located on a side of the MQW layer close to the driving backboard.

According to an embodiment of the present disclosure, the Micro/Nano LED apparatus satisfies at least one of the following conditions: a thickness of the first high-refractive-index layer is 41-42 nm, and a thickness of the first low-refractive-index layer is 77-80 nm; a thickness of the first high-refractive-index layer is 47-48 nm, and a thickness of the first low-refractive-index layer is 89-91 nm; or a thickness of the first high-refractive-index layer is 56-58 nm, and a thickness of the first low-refractive-index layer is 105-109 nm.

According to an embodiment of the present disclosure, the Micro/Nano LED apparatus further includes a third high-refractive-index layer, and the third high-refractive-index layer is located between adjacent first DBR structures; the Micro/Nano LED apparatus further includes an electrode, and the electrode is located on a side of the LED unit away from the driving backboard; the electrode includes a metal electrode layer and an indium tin oxide layer that are arranged in a stacked manner, and the metal electrode layer is located on a side of the indium tin oxide layer close to the LED unit; and the Micro/Nano LED apparatus further includes a passivation layer, the passivation layer covers at least a partial surface of the side of the LED unit away from the driving backboard and a side surface of the LED unit, and there is no overlapping area between an orthographic projection of the passivation layer on the driving backboard and an orthographic projection of the electrode on the driving backboard.

The present disclosure further provides a manufacturing method of a Micro/Nano LED apparatus, including: bonding an LED epitaxial wafer to a driving backboard, etching the bonded LED epitaxial wafer to form a plurality of LED units arranged in an array on the driving backboard; and forming first DBR structures on the driving backboard, so that the first DBR structures are located between adjacent LED units, to obtain a Micro/Nano LED apparatus, wherein the adjacent first DBR structures form a vertical resonant cavity.

According to an embodiment of the present disclosure, the method further includes a step of manufacturing the LED epitaxial wafer, and the manufacturing the LED epitaxial wafer includes: providing a substrate; forming an n-type GaN layer on one side of the substrate; forming an MQW layer on a side of the n-type GaN layer away from the substrate; forming a p-type GaN layer on a side of the MQW layer away from the n-type GaN layer; and forming a plurality of bonding units arranged in an array on a side of the p-type GaN layer away from the MQW layer.

According to an embodiment of the present disclosure, the bonding the LED epitaxial wafer to the driving backboard includes: aligning the LED epitaxial wafer with the driving backboard, so that the bonding units are located between the p-type GaN layer and the driving backboard; and after the bonding the LED epitaxial wafer to the driving backboard and before the etching the bonded LED epitaxial wafer and the driving backboard, the method further includes: lifting off the substrate by using a laser, so that the n-type GaN layer is exposed; and after the forming the LED units, the method further includes: forming the passivation layer on the side of the LED units away from the driving backboard and the side surface of the LED units.

According to an embodiment of the present disclosure, the forming the first DBR structures on the driving backboard includes: depositing a first high-refractive-index material layer on the driving backboard, so that the first high-refractive-index material layer covers the LED units; coating a resist layer on a side of the first high-refractive-index material layer away from the driving backboard, and imprinting the resist layer by using an imprinting mold; and etching by using the imprinted resist layer as a mask to form a third high-refractive-index material layer, a plurality of first high-refractive-index layers arranged at intervals, and first blank areas located between adjacent first high-refractive-index layers, and then depositing a low-refractive-index material in the first blank areas to form first low-refractive-index layers, to obtain the first DBR structures, where the third high-refractive-index material layer is located between adjacent first DBR structures.

According to an embodiment of the present disclosure, the forming the bonding units further includes: forming a multi-period structure on the side of the p-type GaN layer away from the MQW layer, where the multi-period structure includes multiple pairs of second high-refractive-index material layers and second low-refractive-index material layers that are arranged alternately, and the second high-refractive-index material layers and the second low-refractive-index material layers extend in a direction parallel to an extending direction of the substrate; dividing the multi-period structure into a first etching region and a first non-etching region, etching the first etching region, and removing a material in the first etching region, to obtain second blank areas and a plurality of second DBR structures arranged at intervals; and forming the bonding units in the second blank areas.

According to an embodiment of the present disclosure, after the forming the first DRR structure, the method further includes: dividing the third high-refractive-index material layer into a second etching region and a second non-etching region, wherein the second etching region is located in an area of an orthographic projection of the LED unit, etching the second etching region to remove the third high-refractive-index material layer in the second etching region, to obtain a third blank area and the third high-refractive-index layer; and forming the electrode in the third blank area, wherein the electrode includes a metal electrode layer and an indium tin oxide layer that are arranged in a stacked manner, and the metal electrode layer is located on a side of the indium tin oxide layer close to the LED unit.

### BRIEF DESCRIPTION OF THE DRAWINGS

FIG. 1 is a schematic structural diagram of a Micro/Nano LED apparatus according to an embodiment of the present disclosure;

FIG. 2 is a schematic structural diagram of a Micro/Nano LED apparatus according to another embodiment of the present disclosure;

FIG. 3 is a diagram showing a relationship between a reflectivity of a first DBR structure designed according to three target reflection center wavelengths of R, G, and B and wavelength;

FIG. 4 is a diagram showing a relationship between a reflectivity of a first DBR structure designed according to three target reflection center wavelengths of R, G, and B for R light p-polarized light and an incident angle;

FIG. 5 is a diagram showing a relationship between a reflectivity of a first DBR structure designed according to three target reflection center wavelengths of R, G, and B for G light p-polarized light and an incident angle;

FIG. 6 is a diagram showing a relationship between a reflectivity of a first DBR structure designed according to three target reflection center wavelengths of R, G, and B for B light p-polarized light and an incident angle; in FIG. 4, FIG. 5, and FIG. 6, R-DBR refers to the first DBR structure designed according to the R target reflection center wavelength, G-DBR refers to the first DBR structure designed according to the G target reflection center wavelength, and B-DBR refers to the first DBR structure designed according to the B target reflection center wavelength;

FIG. 7 is a cross-sectional view of an LED epitaxial wafer according to an embodiment of the present disclosure;

FIG. 8 is a top view of an LED epitaxial wafer according to an embodiment of the present disclosure;

FIG. 9 is a schematic structural diagram of an LED epitaxial wafer and a driving backboard bonded together according to an embodiment of the present disclosure;

FIG. 10 is a cross-sectional view of an LED unit according to an embodiment of the present disclosure;

FIG. 11 is a cross-sectional view of an imprinting template according to an embodiment of the present disclosure;

FIG. 12 is a top view of an imprinting template according to an embodiment of the present disclosure;

FIG. 13 is a top view of an imprinting template according to another embodiment of the present disclosure;

FIG. 14 is a top view of an imprinting template according to another embodiment of the present disclosure;

FIG. 15 is a schematic structural diagram of a resist layer after imprinting according to an embodiment of the present disclosure;

FIG. 16 is a schematic structural diagram of a first high-refractive-index material layer after etching according to an embodiment of the present disclosure; and

FIG. 17 is a cross-sectional view of a first DBR structure according to an embodiment of the present disclosure.

### REFERENCE NUMERALS

100: driving backboard, 200: LED unit, 210: p-type GaN layer, 220: MQW layer, 230: n-type GaN layer, 300: first DBR structure, 310′: first high-refractive-index material layer, 310: first high-refractive-index layer, 320: first low-refractive-index layer, a: first blank area, 400: bonding unit, 500: second DBR structure, 510: second high-refractive-index layer, 520: second low-refractive-index layer, 600: electrode, 610: metal electrode layer, 620: indium tin oxide layer, 700′: third high-refractive-index material layer, 700: third high-refractive-index layer, 800: passivation layer, 10: substrate, 20: undoped GaN layer, 30: first insulating layer, 40: resist layer, and 50: second insulating layer.

### DETAILED DESCRIPTION OF EMBODIMENTS

The solution of the present disclosure will be explained below in conjunction with embodiments. Those skilled in the art will understand that the following embodiments are only used to illustrate the present disclosure, and should not be construed as limiting the scope of the present disclosure. In the embodiments, the technical or condition not specified will be carried out according to the technical or condition described in the literature in the field or according to the product specification.

The present disclosure provides a Micro/Nano LED apparatus. Referring to FIG. 1, the Micro/Nano LED apparatus includes: a driving backboard 100, a plurality of LED units 200 arranged in an array, and a plurality of first DBR structures 300, where the LED units 200 are located on one side of the driving backboard 100, the first DBR structures 300 are located between adjacent LED units 200, and the adjacent first DBR structures 300 form a vertical resonant cavity. In this way, the light emitted laterally by the LED units 200 may be reflected by the first DBR structures 300, thereby improving the light extraction efficiency. Moreover, by providing the first DBR (Distributed Bragg Reflector) structure on the sidewall of the LED unit 200, when two groups of first DBR structures 300 are placed face to face, a classic Fabry-Perot resonant cavity (F-P cavity) will be formed. The quality factor Q of the resonant cavity can be improved by adjusting the reflectivity of the cavity, thereby realizing gain of the light output intensity of the Micro/Nano LED. The emission spectral half width of the resonant cavity Micro/Nano LED is 1/Q of that without the resonant cavity, and the far-field distribution of the light is determined by the longitudinal mode of the resonant cavity, so that a very small far-field divergence angle can be obtained. That is to say, the design of the present disclosure can improve the extraction efficiency of the transverse magnetic (TM) mode light on the sidewall of the light-emitting pixel mesa, and can improve the crosstalk problem between pixels. The Micro/Nano LED apparatus of the present disclosure has the advantages of high brightness, narrow emission line width, and small divergence angle, and provides a high-quality light engine manufacturing solution for AR products.

It should be noted that the term “DBR” refers to distributed Bragg reflection, also known as distributed Bragg reflector, which is a periodic structure composed of two materials with different refractive indexes arranged alternately in an ABAB manner.

According to some embodiments of the present disclosure, the driving backboard 100 may be a CMOS driving backboard, and the driving backboard 100 is used to provide electrical signals to the LED units 200 to control the brightness.

According to an embodiment of the present disclosure, the first DBR structure 300 includes multiple pairs of first high-refractive-index layers 310 and first low-refractive-index layers 320 that are arranged alternately; referring to FIG. 1, the first high-refractive-index layers 310 and the first low-refractive-index layers 320 are perpendicular to the driving backboard 100.

According to an embodiment of the present disclosure, referring to FIG. 1, the Micro/Nano LED apparatus further includes a plurality of bonding units 400 arranged at intervals, and the bonding units 400 are located between the driving backboard 100 and the LED units 200.

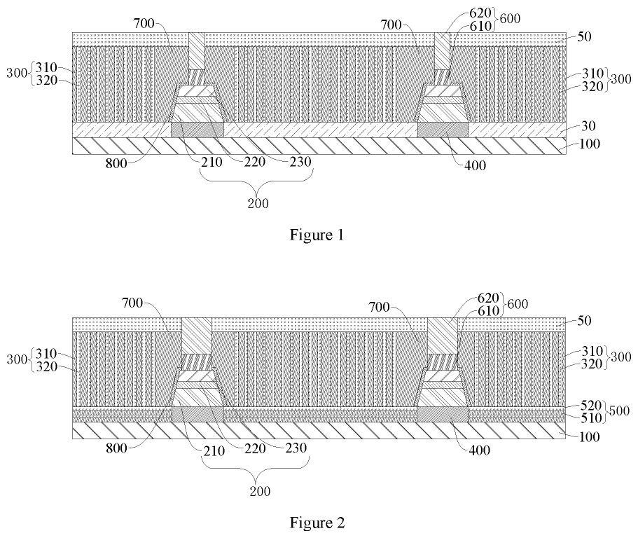

According to an embodiment of the present disclosure, referring to FIG. 2, the Micro/Nano LED apparatus further includes second DBR structures 500, the second DBR structures 500 are located between adjacent bonding units 400, and the second DBR structures 500 are located on a side of the first DBR structures 300 close to the driving backboard 100; a side of the LED units 200 away from the driving backboard 100 is provided with a metal electrode layer 610; and the metal electrode layer 610 and the second DBR structures 500 form a horizontal resonant cavity. In this way, the light emitted downward by the LED units 200 may be reflected to the metal electrode layer 610 by the second DBR structures 500, and then emitted in a directional manner from the metal electrode layer 610. Moreover, the design of the present disclosure may also form F-P cavities in the upper and lower regions of the LED unit 200 (light-emitting mesa), thereby realizing full coverage of the three-dimensional F-P cavity. Moreover, the horizontal resonant cavity may also reduce the full width at half maximum of the emission spectrum, and obtain a very small far-field divergence angle and ultra-high brightness gain. In addition, the Micro/Nano LED apparatus of the present disclosure may focus the large divergence angle light output of the traditional Micro/Nano LED cosine radiation type within a very small divergence angle (±20°), thereby greatly reducing the energy loss coupled into the AR diffractive optical waveguide, and realizing high brightness and high contrast AR micro display.

According to an embodiment of the present disclosure, a material for forming the metal electrode layer 610 includes at least one of silver, aluminum, and gold; further, silver and aluminum have a relatively high reflectivity, and when the material for forming the metal electrode layer 610 is silver or aluminum, the metal electrode layer 610 and the second DBR structures 500 form the horizontal resonant cavity.

According to an embodiment of the present disclosure, the second DBR structure 500 includes multiple pairs of second high-refractive-index layers 510 and second low-refractive-index layers 520 that are arranged alternately; referring to FIG. 2, the second high-refractive-index layers 510 and the second low-refractive-index layers 520 are parallel to an extending direction of the driving backboard 100.

According to some embodiments of the present disclosure, a material for forming the first high-refractive-index layers 310 and a material for forming the second high-refractive-index layers 510 include TiO₂, and a material for forming the first low-refractive-index layers 320 and a material for forming the second low-refractive-index layers 520 include SiO₂.

According to some embodiments of the present disclosure, the first DBR structure 300 includes multiple periods, each period of the first DBR structure 300 includes a first high-refractive-index layer 310 and a first low-refractive-index layer 320 that are arranged in a stacked manner, and the first DBR structure 300 includes 10 periods. That is to say, the first DBR structure 300 may include 10 pairs of identical structures, and each pair of structures includes a first high-refractive-index layer 310 and a first low-refractive-index layer 320 arranged on the first high-refractive-index layer 310.

According to some embodiments of the present disclosure, the second DBR structure 500 includes multiple periods, each period of the second DBR structure 500 includes a second high-refractive-index layer 510 and a second low-refractive-index layer 520 that are arranged in a stacked manner, and the second DBR structure 500 includes 15 or more periods; specifically, the second DBR structure 500 may include 15-20 periods, for example, the second DBR structure 500 may include 15, 16, 17, 18, 19, or 20 periods.

According to some embodiments of the present disclosure, a thickness of the second high-refractive-index layer 510 is the same as that of the first high-refractive-index layer 310, and a thickness of the second low-refractive-index layer 520 is the same as that of the first low-refractive-index layer 320.

According to some embodiments of the present disclosure, the LED unit 200 includes a p-type GaN layer 210, an MQW layer 220, and an n-type GaN layer 230 that are arranged in a stacked manner, and the p-type GaN layer 210 is located on a side of the MQW layer 220 close to the driving backboard 100.

The term “MQW” refers to multiple quantum well, which refers to a system in which multiple quantum wells are combined together.

According to some embodiments of the present disclosure, the component of In in the MQW layer 220 determines the color of the light emitted by the LED unit 200. The MQW layer 220 may emit blue light with a wavelength of 455-465 nm (for example, 455 nm or 465 nm), the MQW layer 220 may also emit green light with a wavelength of 525-535 nm (for example, 525 nm or 535 nm), and the MQW layer 220 may also emit red light with a wavelength of 620-640 nm (for example, 620 nm or 640 nm).

According to some embodiments of the present disclosure, the Fabry-Perot resonant cavity (F-P cavity) may be designed in a targeted manner according to different emission colors of the LED units 200. The present disclosure adopts the first DBR structure 300 as the mirror surface of the F-P cavity, and the first DBR structure 300 is formed by periodically superimposing the first high-refractive-index layers 310 and the first low-refractive-index layers 320. The reflectivity expression of the first DBR structure 300 is

$$R = {( \frac{{nH}^{2 N} - {nL}^{2 N}}{{nH}^{2 N} + {nL}^{2 N}} )}^{2} ,$$

where n_{H} is the refractive index of the first high-refractive-index layer 310, n is the refractive index of the first low-refractive-index layer 320, N is the logarithm of the first high-refractive-index layer 310 and the first low-refractive-index layer 320 in the first DBR structure 300, and one pair includes one first high-refractive-index layer 310 and one first low-refractive-index layer 320. In the present disclosure, the material for forming the first high-refractive-index layer 310 is preferably TiO₂, the refractive index of TiO₂ is 2.78, the material for forming the first low-refractive-index layer 320 is preferably SiO₂, the refractive index of SiO₂ is 1.47, and Nis preferably 10. The thicknesses of the first high-refractive-index layer 310 and the first low-refractive-index layer 320 are determined by the center wavelength of the target reflected light, and the thickness

$$d = \frac{λ}{4 \times n} ,$$

where λ is the center wavelength of the target reflected light, and n is the corresponding refractive index.

According to an embodiment of the present disclosure, the Micro/Nano LED apparatus satisfies at least one of the following conditions:
when the center wavelength of the target reflected light is 455-465 nm (B), the thickness of the first high-refractive-index layer 310 is 41-42 nm, and the thickness of the first low-refractive-index layer 320 is 77-80 nm;
when the center wavelength of the target reflected light is 525-535 nm (G), the thickness of the first high-refractive-index layer 310 is 47-48 nm, and the thickness of the first low-refractive-index layer 320 is 89-91 nm;
when the center wavelength of the target reflected light is 620-640 nm (R), the thickness of the first high-refractive-index layer 310 is 56-58 nm, and the thickness of the first low-refractive-index layer 320 is 105-109 nm.

The above is the design of the first DBR structure for the LED units with different emission colors. It should be noted that the Micro/Nano LED apparatus includes a plurality of LED units arranged in an array, and the plurality of LED units may have the same or different emission colors. When the plurality of LED units have different emission colors, the first DBR structure 300 in the Micro/Nano LED apparatus may satisfy the above two conditions, or satisfy the above three conditions. For example, the Micro/Nano LED apparatus includes an LED unit that emits red light (R), an LED unit that emits green light (G), and an LED unit that emits blue light (B). The thickness of the first high-refractive-index layer 310 of the first DBR structure around the LED unit that emits red light (R) is 56-58 nm, and the thickness of the first low-refractive-index layer 320 is 105-109 nm. The thickness of the first high-refractive-index layer 310 of the first DBR structure around the LED unit that emits green light (G) is 47-48 nm, and the thickness of the first low-refractive-index layer 320 is 89-91 nm. The thickness of the first high-refractive-index layer 310 of the first DBR structure around the LED unit that emits blue light (B) is 41-42 nm, and the thickness of the first low-refractive-index layer 320 is 77-80 nm.

Specifically, when the center wavelength of the target reflected light is 465 nm (B), the thicknesses of the corresponding TiO₂ layer and SiO₂ layer are 42 nm and 80 nm, respectively. When the center wavelength of the target reflected light is 525 nm (G), the thicknesses of the corresponding TiO₂ layer and SiO₂ layer are 47 nm and 89 nm, respectively. When the center wavelength of the target reflected light is 620 nm (R), the thicknesses of the corresponding TiO₂ layer and SiO₂ layer are 56 nm and 105 nm, respectively.

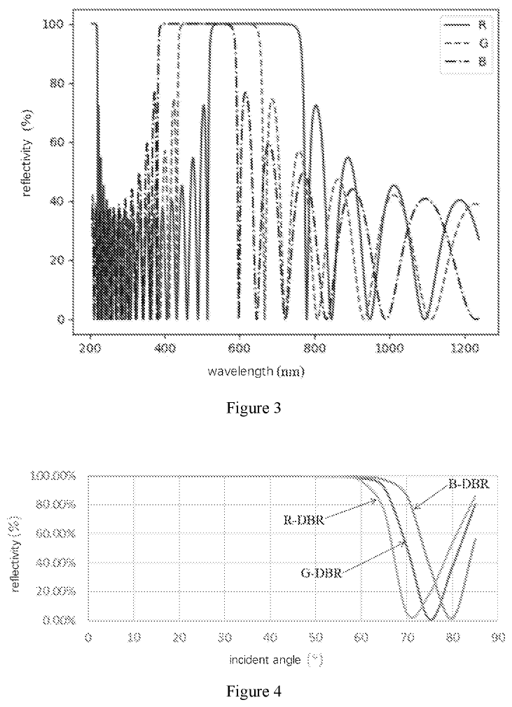

FIG. 3 is a diagram showing a relationship between a reflectivity of a first DBR structure 300 designed according to three target reflection center wavelengths of R, G, and B and a wavelength. It can be seen from FIG. 3 that when the wavelength is 620-640 nm, the reflectivity of the first DBR structure 300 designed according to the R target reflection center wavelength is 100%. When the wavelength is 525-535 nm, the reflectivity of the first DBR structure 300 designed according to the G target reflection center wavelength is 100%. When the wavelength is 455-465 nm, the reflectivity of the first DBR structure 300 designed according to the B target reflection center wavelength is 100%. Therefore, in the present disclosure, the first DBR structure 300 is arranged between the adjacent LED units 200, which may converge the divergence angle of the light output, reduce the optical crosstalk between pixels, and improve the light extraction efficiency.

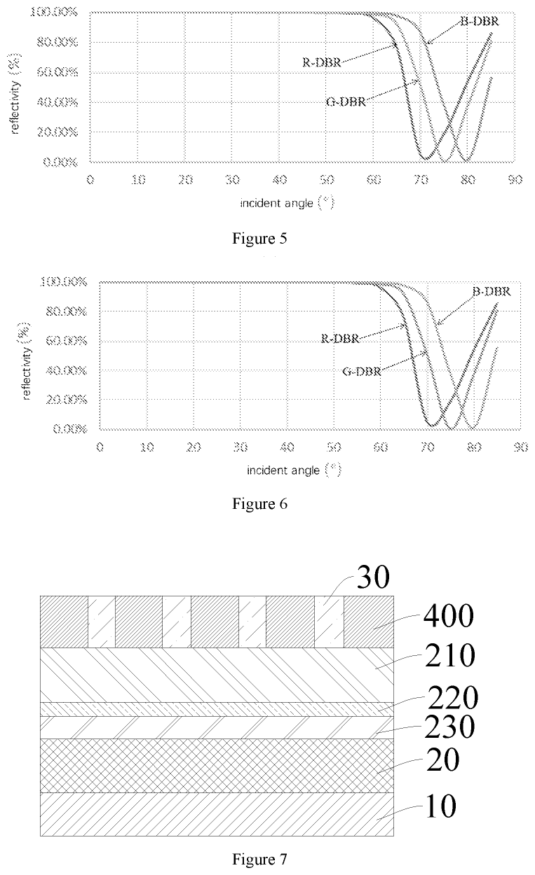

According to strict calculation based on Maxwell equations and Fresnel equations, the first DBR structure 300 designed according to the three target reflection center wavelengths of R, G, and B has different reflectivity to incident light of different polarization states with different incident angles. The present disclosure provides the relationship between the reflectivity of the first DBR structure 300 designed according to the three target reflection center wavelengths of R, G, and B to the incident p-polarized light corresponding to R, G, and B, respectively, and the incident angle, as shown in FIG. 4, FIG. 5, and FIG. 6, respectively. It can be seen from FIG. 4, FIG. 5, and FIG. 6 that the first DBR structure designed according to the B target reflection center wavelength has the highest Brewster angle for the p-polarized light of the three incident lights of R, G, and B. In the present disclosure, the first DBR structure 300 is arranged between the adjacent LED units 200, which is beneficial for the light emitted by the LED unit 200 to have a relatively small incident angle when irradiating the surface of the first DBR structure 300, thereby having a relatively high reflectivity, which is beneficial for the light to be emitted to the side of the light-emitting surface of the LED unit 200. That is to say, the placement position of the first DBR structure 300 in the present disclosure may improve the light extraction efficiency.

According to an embodiment of the present disclosure, referring to FIG. 1 and FIG. 2, the Micro/Nano LED apparatus further includes a third high-refractive-index layer 700, and the third high-refractive-index layer 700 is located between adjacent first DBR structures 300.

According to some embodiments of the present disclosure, a material for forming the third high-refractive-index layer 700 includes TiO₂.

According to some embodiments of the present disclosure, referring to FIG. 1 and FIG. 2, the Micro/Nano LED apparatus further includes an electrode 600, and the electrode 600 is located on a side of the LED unit 200 away from the driving backboard 100; the electrode 600 includes a metal electrode layer 610 and an indium tin oxide layer 620 that are arranged in a stacked manner, and the metal electrode layer 610 is located on a side of the indium tin oxide layer 620 close to the LED unit 200. By providing the electrode 600, it is beneficial to form an interconnection of n-type electrodes of the light-emitting mesa.

According to some embodiments of the present disclosure, referring to FIG. 1 and FIG. 2, the Micro/Nano LED apparatus further includes a passivation layer 800, and the passivation layer 800 covers at least a partial surface of the side of the LED unit 200 away from the driving backboard 100 and a side surface of the LED unit 200, and there is no overlapping area between an orthographic projection of the passivation layer 800 on the driving backboard 100 and an orthographic projection of the electrode 600 on the driving backboard 100. In this way, the passivation layer 800 may be used to protect and isolate the LED unit 200.

According to some embodiments of the present disclosure, a material for forming the passivation layer 800 includes at least one of SiO₂, Al₂O₃.

The present disclosure further provides a manufacturing method of a Micro/Nano LED apparatus, including:
S100, bonding an LED epitaxial wafer to a driving backboard 100, etching the bonded LED epitaxial wafer, and forming a plurality of LED units 200 arranged in an array on the driving backboard 100; and
by providing the plurality of LED units 200 arranged in an array, it is beneficial for the LED units 200 to be driven independently.

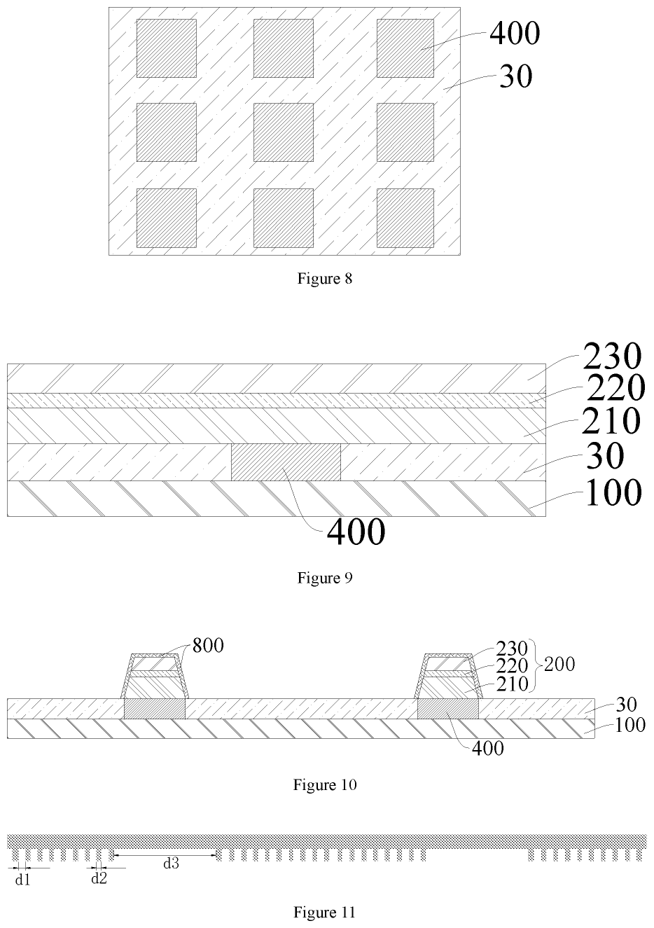

According to an embodiment of the present disclosure, the method further includes a step of manufacturing the LED epitaxial wafer. Referring to FIG. 7 and FIG. 8, the manufacturing the LED epitaxial wafer includes:
S110, providing a substrate 10;
according to some embodiments of the present disclosure, the substrate 10 includes any one of sapphire and silicon.

According to some embodiments of the present disclosure, the LED epitaxial wafer may be grown on the substrate 10 by using MOCVD.
S120, forming an n-type GaN layer 230 on one side of the substrate 10;
according to some embodiments of the present disclosure, the forming the n-type GaN layer 230 includes: forming an undoped GaN layer 20 (u-GaN) on one side of the substrate 10, and then forming the n-type GaN layer 230 (n-GaN) on a side of the undoped GaN layer 20 (u-GaN) away from the substrate 10.

According to some embodiments of the present disclosure, the thickness of the undoped GaN layer 20 may be 2.5 μm, and the thickness of the n-type GaN layer 230 may be 1 μm. Further, the n-type GaN layer 230 may use Si as a dopant.
S130, forming an MQW layer 220 on a side of the n-type GaN layer 230 away from the substrate 10;
according to some embodiments of the present disclosure, the MQW layer 220 is an InGaN multiple quantum well light-emitting active region in 5 periods with a total thickness of 150 nm.

S140, forming a p-type GaN layer 210 on a side of the MQW layer 220 away from the n-type GaN layer 230;
according to some embodiments of the present disclosure, the Micro/Nano LED apparatus may further include an electron blocking layer, and the electron blocking layer is located between the MQW layer 220 and the p-type GaN layer 210 (p-GaN). The sum of the thickness of the electron blocking layer and the thickness of the p-type GaN layer 210 may be 100 nm. Further, the p-type GaN layer 210 may use Mg as a dopant.

S150, forming a plurality of bonding units 400 arranged in an array on a side of the p-type GaN layer 210 away from the MQW layer 220.

According to some embodiments of the present disclosure, after the forming the p-type GaN layer 210 and before the forming the bonding units 400, the method includes: forming a first insulating material layer on the side of the p-type GaN layer 210 away from the MQW layer 220, where the first insulating material layer includes a plurality of etching regions arranged in an array and non-etching regions located between the etching regions; then etching the etching regions of the first insulating material layer by using a photolithography process and an ICP-RIE (Inductively Coupled Plasma-Reaction Ion Etching) etching process, and removing the insulating material in the etching regions, to form a plurality of first insulating layers 30 arranged at intervals; and then forming the bonding units 400 in the etching regions by using an electron beam evaporation process, where the bonding units 400 are located between adjacent first insulating layers 30.

According to some embodiments of the present disclosure, the material for forming the first insulating material layer and the material for forming the first insulating layer 30 may be SiO₂, the first insulating material layer may be deposited by using a PECVD (Plasma Enhanced Chemical Vapor Deposition) process, and the thickness of the first insulating material layer and the thickness of the first insulating layer 30 may be 530 nm.

According to other embodiments of the present disclosure, the first insulating layer 30 may have the structure of the second DBR structure 500. Further, the second DBR structure 500 may be fabricated by using a magnetron sputtering process.

According to other embodiments of the present disclosure, the forming the bonding units 400 further includes:
S151, forming a multi-period structure on the side of the p-type GaN layer 210 away from the MQW layer 220, where the multi-period structure includes multiple pairs of second high-refractive-index material layers and second low-refractive-index material layers that are arranged alternately, each period of the multi-period structure has the same structure, and the second high-refractive-index material layers and the second low-refractive-index material layers extend in a direction parallel to an extending direction of the substrate 10;
S152, dividing the multi-period structure into first etching regions and first non-etching regions, etching the first etching regions, and removing a material in the first etching regions, to obtain second blank areas and a plurality of second DBR structures 500 arranged at intervals; and
S153, forming the bonding units 400 in the second blank areas.

According to some embodiments of the present disclosure, the material for forming the bonding units 400 includes any one of Ni—Sn and Au—Sn. For example, the Au—Sn alloy may have a weight content of Au of 78% and a weight content of Sn of 22%.

According to some embodiments of the present disclosure, the thickness of the bonding unit 400 may be 0.03-2 μm, for example, 30 nm, 500 nm, 1 μm, 1.6 μm, or 2 μm.

According to some embodiments of the present disclosure, the length of each bonding unit 400 may be 0.5-3 μm, the width of each bonding unit 400 may be 0.5-3 μm, and the spacing between the centers of adjacent bonding units 400 may be 2-2.5 μm.

According to some embodiments of the present disclosure, after the forming the bonding unit 400, the method further includes: performing rapid thermal annealing for 3-5 minutes in an oxygen or air atmosphere to form an ohmic connection with the p-type GaN layer 210. A cross-sectional view of the structure after the manufacturing is completed is shown in FIG. 7. Then, ultrasonic treatment is performed in an acetone solution for 10 minutes, and then rinsing is performed with deionized water for 15 minutes to clean the surface. A top view of the completed structure is shown in FIG. 8.

According to some embodiments of the present disclosure, the driving backboard 100 is distributed with a plurality of metal layers arranged in an array. The material for forming the metal layers may be Al. The length of the metal layers may be 0.5-3 μm, the width of the metal layers may be 0.5-3 μm, and the spacing between the centers of adjacent metal layers may be 2.5-5 μm. The bonding units 400 of the LED epitaxial wafer are aligned with the metal layers on the driving backboard 100, so that the bonding between the LED epitaxial wafer and the driving backboard 100 may be realized.

According to an embodiment of the present disclosure, referring to FIG. 9, the bonding the LED epitaxial wafer to the driving backboard 100 includes: aligning the LED epitaxial wafer with the driving backboard 100, so that the bonding units 400 are located between the p-type GaN layer 210 and the driving backboard 100. Specifically, the eutectic bonding process may be used to complete the bonding.

According to some embodiments of the present disclosure, after the bonding the LED epitaxial wafer to the driving backboard 100 and before the etching the bonded LED epitaxial wafer and the driving backboard 100, the method further includes: lifting off the substrate 10 by using a laser, so that the n-type GaN layer 230 is exposed.

According to some embodiments of the present disclosure, the sapphire substrate 10 may be lifted off by using a laser with a wavelength of 255 nm picoseconds, and the undoped GaN layer 20 (u-GaN) may be completely etched away by using the ICP-RIE etching process, so that the n-type GaN layer 230 is exposed. A structure of one LED unit 200 after the manufacturing is completed is shown in FIG. 9.

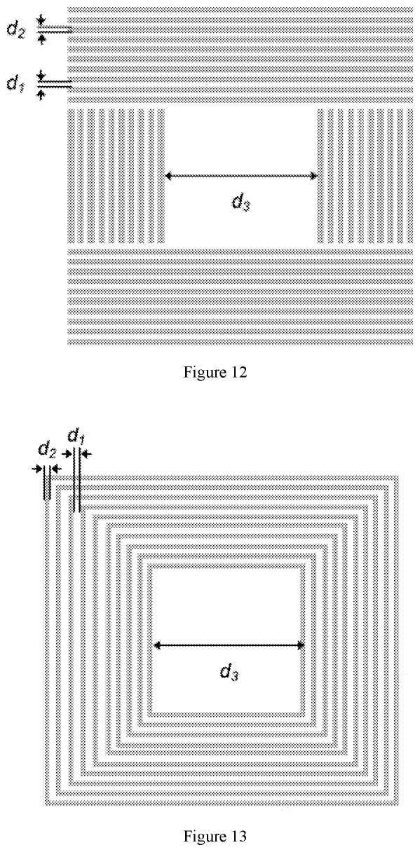

On the basis of the structure in FIG. 9, the bonded LED epitaxial wafer is etched by using the photolithography process and the ICP-RIE process, to form a plurality of LED units 200 (pixel mesas) arranged in an array on the driving backboard 100. A structure of two LED units 200 after the manufacturing is completed is shown in FIG. 10.

According to some embodiments of the present disclosure, the length of the LED unit 200 may be 0.5-3 μm, the width of the LED unit 200 may be 0.5-3 μm, the height of the LED unit 200 may be 1.25 μm, the spacing between the centers of adjacent LED units 200 may be 2.5-5 μm, and the inclination angle of the pixel mesa is greater than 80°.

According to some embodiments of the present disclosure, after the forming the LED unit 200, the method further includes: forming the passivation layer 800 on the side of the LED unit 200 away from the driving backboard 100 and the side surface of the LED unit 200. Specifically, the passivation layer 800 may be formed by using an atomic layer deposition (ALD) process. Further, the thickness of the passivation layer 800 may be 20 nm. By providing the passivation layer 800, it is beneficial to repair etching damage.

S200, forming the first DBR structures 300 on the driving backboard 100, so that the first DBR structures 300 are located between the adjacent LED units 200, to obtain a Micro/Nano LED apparatus, wherein the adjacent first DBR structures 300 form the vertical resonant cavity.

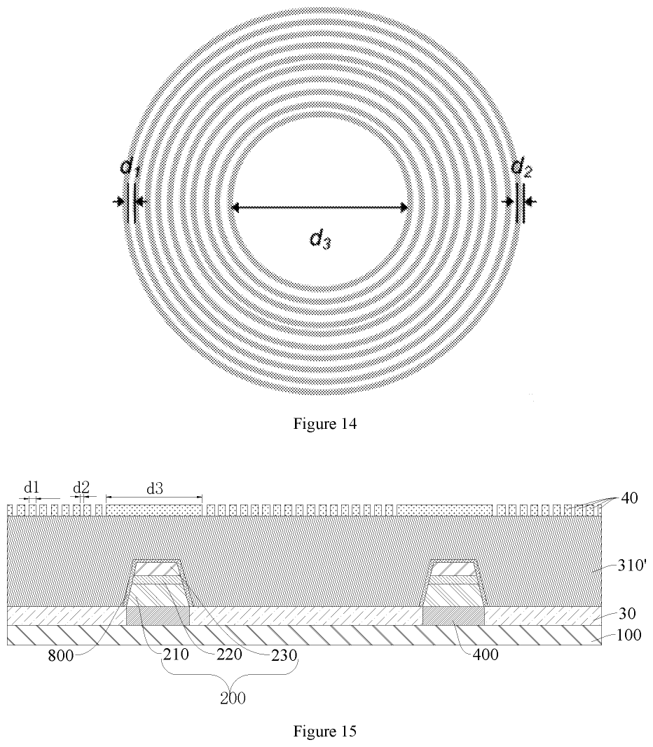

The DBR having the above-mentioned structure may be manufactured by using the method of nanoimprinting and ICP-RIE etching. A cross-sectional view of the imprinting template used in the present disclosure is shown in FIG. 11, and top views of the imprinting template are shown in FIG. 12, FIG. 13, or FIG. 14, where d1 corresponds to the thickness of a high-refractive-index material (the first high-refractive-index layer 310 and the second high-refractive-index layer 510, for example, TiO₂), d2 corresponds to the thickness of a low-refractive-index material (the first low-refractive-index layer 320 and the second low-refractive-index layer 520, for example, SiO₂), and d3 corresponds to the length of the F-P cavity, and d3 is preferably 0.7-3.2 μm. Further, the imprinting template may be fabricated on the Si wafer by using an electron beam lithography process.

According to an embodiment of the present disclosure, the forming the first DBR structures 300 on the driving backboard 100 includes:
S210, depositing a first high-refractive-index material layer 310′ on the driving backboard 100, so that the first high-refractive-index material layer 310′ covers the LED units 200; and
according to some embodiments of the present disclosure, referring to FIG. 15, the first high-refractive-index material layer 310′ may be deposited on the driving backboard 100 by using a magnetron sputtering method. The first high-refractive-index material layer 310′ may be a TiO₂ layer, and the thickness of the first high-refractive-index material layer 310′ may be 1.8-2 μm.

S220, coating a resist layer 40 on a side of the first high-refractive-index material layer 310′ away from the driving backboard 100, and imprinting the resist layer 40 by using an imprinting mold;
through the imprinting step, the transfer of the imprinted pattern may be realized. Specifically, through imprinting, curing, and demolding, the pattern on the imprinting mold may be transferred and imprinted to the resist layer 40, and the manufactured structure is shown in FIG. 15.

S230, etching by using the imprinted resist layer 40 as a mask, to form a third high-refractive-index material layer 700′, a plurality of first high-refractive-index layers 310 arranged at intervals, and first blank areas a located between adjacent first high-refractive-index layers 310, and then depositing a low-refractive-index material in the first blank areas a to form first low-refractive-index layers 320, to obtain the first DBR structures 300, where the third high-refractive-index material layer 700′ is located between adjacent first DBR structures 300.

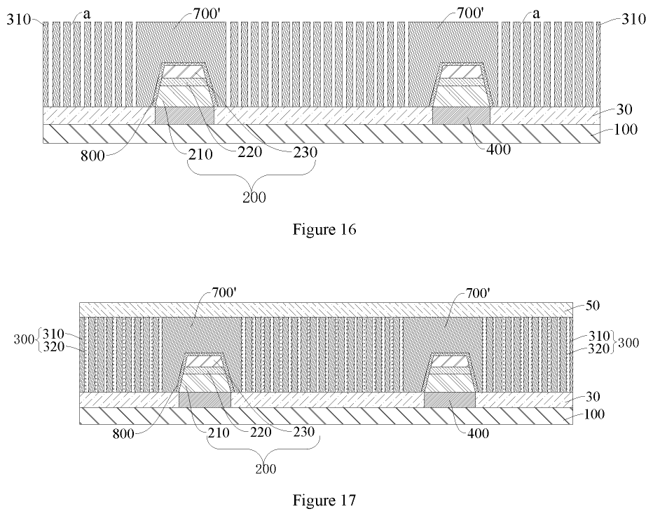

The first high-refractive-index material layer 310′ is etched by using the ICP-RIE with the imprinted resist layer 40 as an etching mask to remove the high-refractive-index material (for example, TiO₂) in the low-refractive-index region. A structure after the imprinted glue is removed is shown in FIG. 16. The low-refractive-index material (for example, SiO₂) is deposited on the structure in FIG. 16 by using the PECVD, so that the low-refractive-index material (for example, SiO₂) completely fills the etched first blank areas a in FIG. 16, and the first DBR structures 300 may be formed between the adjacent LED units 200. Then the second insulating layer 50 may be formed on a side of the first DBR structure 300 away from the driving backboard 100. The second insulating layer 50 is used to protect the first DBR structure 300, and the completed structure is shown in FIG. 17.

According to some embodiments of the present disclosure, the material for forming the second insulating layer 50 may be SiO₂.

According to some embodiments of the present disclosure, the deposition thickness of the low-refractive-index material (for example, SiO₂) may be 2.5-3 μm, the low-refractive-index material with a portion of the thickness may be filled between the adjacent first high-refractive-index layers 310 as the first low-refractive-index layer 320, and the low-refractive-index material with another portion of the thickness may be deposited above the first DBR structure 300 as the second insulating layer 50, to protect the first DBR structure 300.

According to an embodiment of the present disclosure, after the forming the first DRR structure, the method further includes: dividing the third high-refractive-index material layer 700′ into a second etching region and a second non-etching region, where the second etching region is located in an area of an orthographic projection of the LED unit 200, etching the second etching region to remove the third high-refractive-index material layer 700′ in the second etching region, to obtain a third blank area and the third high-refractive-index layer 700; and forming the electrode 600 in the third blank area, wherein the electrode 600 includes a metal electrode layer 610 and an indium tin oxide layer 620 that are arranged in a stacked manner, and the metal electrode layer 610 is located on a side of the indium tin oxide layer 620 close to the LED unit 200.

According to some embodiments of the present disclosure, etching the second etching region further requires removing the passivation layer 800 located in the second etching region and the material of the second insulating layer 50 located in the second etching region.

Specifically, the passivation layer 800, the third high-refractive-index material layer 700′ (TiO₂), and the second insulating layer 50 (SiO₂) directly above the light-emitting LED unit 200 may be removed by using the photolithography process and the ICP-RIE process. Then, the metal electrode layer 610 (for example, Au, Ag, or Al with a thickness of 500 nm) and the indium tin oxide layer 620 (for example, indium tin oxide with a thickness of 3-4 μm) are deposited in the area where the third high-refractive-index material layer 700′ (TiO₂) is removed by using electron beam evaporation and magnetron sputtering, so that the n-type electrodes of the light-emitting mesa are interconnected. The completed structure is shown in FIG. 1 or FIG. 2.

It should be noted that in this specification, the terms “first”, “second”, and “third” are only used for descriptive purposes, and should not be construed as indicating or implying relative importance or implying the number of indicated technical features. In the description of the present disclosure, it should be understood that the orientation or positional relationship indicated by the terms “upper”, “lower”, “inner”, “outer”, etc. is based on the orientation or positional relationship shown in the drawings, which is only for the convenience of describing the present disclosure and simplifying the description, and does not indicate that the device or component referred to must have a specific orientation or be configured or operated in a specific orientation, and thus should not be construed as limiting the present disclosure.

In the description of this specification, the description referring to the terms “an embodiment”, “another embodiment”, “some embodiments”, “an example”, “a specific example”, or “some examples” and the like means that the specific features, structures, materials, or characteristics described in conjunction with the embodiments or examples are included in at least one embodiment or example of the present disclosure. In this specification, the schematic representations of the above terms are not necessarily directed to the same embodiments or examples. Moreover, the described specific features, structures, materials, or characteristics may be combined in any one or more embodiments or examples in an appropriate manner. In addition, those skilled in the art may incorporate and combine different embodiments or examples and features of different embodiments or examples described in this specification without contradiction.

Although the embodiments of the present disclosure have been shown and described above, it may be understood that the above embodiments are illustrative and should not be construed as limiting the present disclosure, and those skilled in the art may make changes, modifications, replacements, and variations to the above embodiments within the scope of the present disclosure.

1. A Micro/Nano LED apparatus, comprising: a driving backboard, a plurality of LED units arranged in an array, and a plurality of first DBR structures,
wherein the LED units are located on one side of the driving backboard, the first DBR structures are located between adjacent LED units, and adjacent first DBR structures form a vertical resonant cavity.

2. The Micro/Nano LED apparatus according to claim 1, wherein the first DBR structure comprises a plurality of pairs of first high-refractive-index layers and first low-refractive-index layers that are arranged alternately; and
the first high-refractive-index layers and the first low-refractive-index layers are perpendicular to the driving backboard.

3. The Micro/Nano LED apparatus according to claim 2, wherein the Micro/Nano LED apparatus further comprises a plurality of bonding units arranged at intervals, and the bonding units are located between the driving backboard and the LED units.

4. The Micro/Nano LED apparatus according to claim 3, wherein the Micro/Nano LED apparatus further comprises second DBR structures, the second DBR structures are located between adjacent bonding units, and the second DBR structures are located on a side of the first DBR structures close to the driving backboard;
a side of the LED units away from the driving backboard is provided with a metal electrode layer; and
the metal electrode layer and the second DBR structures form a horizontal resonant cavity.

5. The Micro/Nano LED apparatus according to claim 4, wherein a material for forming the metal electrode layer comprises at least one of silver, aluminum, and gold;
the second DBR structure comprises a plurality of pairs of second high-refractive-index layers and second low-refractive-index layers that are arranged alternately; and
the second high-refractive-index layers and the second low-refractive-index layers are parallel to the driving backboard.

6. The Micro/Nano LED apparatus according to claim 5, wherein the Micro/Nano LED apparatus satisfies at least one of the following conditions:
a material for forming the first high-refractive-index layers and a material for forming the second high-refractive-index layers comprise TiO₂;
a material for forming the first low-refractive-index layers and a material for forming the second low-refractive-index layers comprise SiO₂;
the first DBR structure comprises a plurality of periods, each period of the first DBR structure comprises a first high-refractive-index layer and a first low-refractive-index layer that are arranged in a stacked manner, and the first DBR structure comprises 10 periods;
the second DBR structure comprises a plurality of periods, each period of the second DBR structure comprises a second high-refractive-index layer and a second low-refractive-index layer that are arranged in a stacked manner, and the second DBR structure comprises 15 or more periods;
a thickness of the second high-refractive-index layer is the same as that of the first high-refractive-index layer, and a thickness of the second low-refractive-index layer is the same as that of the first low-refractive-index layer; or
the LED unit comprises a p-type GaN layer, an MQW layer, and an n-type GaN layer that are arranged in a stacked manner, and the p-type GaN layer is located on a side of the MQW layer close to the driving backboard.

7. The Micro/Nano LED apparatus according to claim 2, wherein the Micro/Nano LED apparatus satisfies at least one of the following conditions:
a thickness of the first high-refractive-index layer is 41-42 nm, and a thickness of the first low-refractive-index layer is 77-80 nm;
a thickness of the first high-refractive-index layer is 47-48 nm, and a thickness of the first low-refractive-index layer is 89-91 nm; or
a thickness of the first high-refractive-index layer is 56-58 nm, and a thickness of the first low-refractive-index layer is 105-109 nm.

8. The Micro/Nano LED apparatus according to claim 1, wherein the Micro/Nano LED apparatus further comprises a third high-refractive-index layer, and the third high-refractive-index layer is located between adjacent first DBR structures.

9. The Micro/Nano LED apparatus according to claim 1, wherein the Micro/Nano LED apparatus further comprises an electrode, and the electrode is located on a side of the LED unit away from the driving backboard; and the electrode comprises a metal electrode layer and an indium tin oxide layer that are arranged in a stacked manner, and the metal electrode layer is located on a side of the indium tin oxide layer close to the LED unit.

10. The Micro/Nano LED apparatus according to claim 9, wherein the Micro/Nano LED apparatus further comprises a passivation layer, and the passivation layer covers at least a partial surface of the side of the LED unit away from the driving backboard and a side surface of the LED unit, and there is no overlapping area between an orthographic projection of the passivation layer on the driving backboard and an orthographic projection of the electrode on the driving backboard.

11. A manufacturing method of a Micro/Nano LED apparatus, the method comprising:
bonding an LED epitaxial wafer to a driving backboard, etching the bonded LED epitaxial wafer, and forming a plurality of LED units arranged in an array on the driving backboard; and
forming first DBR structures on the driving backboard so as to locate the first DBR structures between the adjacent LED units, and thus obtaining the Micro/Nano LED apparatus,
wherein the adjacent first DBR structures form a vertical resonant cavity.

12. The manufacturing method according to claim 11, wherein the method further comprises a step of manufacturing the LED epitaxial wafer; and
the manufacturing the LED epitaxial wafer comprises:
providing a substrate;
forming an n-type GaN layer on one side of the substrate;
forming an MQW layer on a side of the n-type GaN layer away from the substrate;
forming a p-type GaN layer on a side of the MQW layer away from the n-type GaN layer; and
forming a plurality of bonding units arranged in an array on a side of the p-type GaN layer away from the MQW layer.

13. The manufacturing method according to claim 12, wherein the bonding the LED epitaxial wafer to the driving backboard comprises: aligning the LED epitaxial wafer with the driving backboard, so that the bonding units are located between the p-type GaN layer and the driving backboard;
after the bonding the LED epitaxial wafer to the driving backboard and before the etching the bonded LED epitaxial wafer and the driving backboard, the method further comprises: lifting-off the substrate by using a laser, so that the n-type GaN layer is exposed; and
after the forming the LED units, the method further comprises: forming a passivation layer on a side of the LED unit away from the driving backboard and a side surface of the LED unit.

14. The manufacturing method according to claim 11, wherein the forming the first DBR structures on the driving backboard comprises:
depositing a first high-refractive-index material layer on the driving backboard, so that the first high-refractive-index material layer covers the LED units;
coating a resist layer on a side of the first high-refractive-index material layer away from the driving backboard, and imprinting the resist layer by using an imprinting mold; and
etching by using the imprinted resist layer as a mask to form a third high-refractive-index material layer, a plurality of first high-refractive-index layers arranged at intervals, and first blank areas located between the adjacent first high-refractive-index layers, and then depositing a low-refractive-index material in the first blank areas to form first low-refractive-index layers, to obtain the first DBR structures, wherein the third high-refractive-index material layer is located between adjacent first DBR structures.

15. The manufacturing method according to claim 12, wherein the forming the bonding units further comprises:
forming a multi-period structure on the side of the p-type GaN layer away from the MQW layer, wherein the multi-period structure comprises a plurality of pairs of second high-refractive-index material layers and second low-refractive-index material layers that are arranged alternately, and the second high-refractive-index material layers and the second low-refractive-index material layers extend in a direction parallel to an extending direction of the substrate;
dividing the multi-period structure into a first etching region and a first non-etching region, etching the first etching region, and removing a material in the first etching region, so as to obtain second blank areas and a plurality of second DBR structures arranged at intervals; and
forming the bonding units in the second blank areas.

16. The manufacturing method according to claim 14, wherein after the forming the first DBR structure, the method further comprises: dividing the third high-refractive-index material layer into a second etching region and a second non-etching region, wherein the second etching region is located in an area of an orthographic projection of the LED unit, etching the second etching region to remove the third high-refractive-index material layer in the second etching region, so as to obtain a third blank area and the third high-refractive-index layer; and
forming the electrode in the third blank area, wherein the electrode comprises a metal electrode layer and an indium tin oxide layer that are arranged in a stacked manner, and the metal electrode layer is located on a side of the indium tin oxide layer close to the LED unit.
